(19) United States
(12) Patent Application Publication
(10) Pub. No.: US 2010/0018030 A1
(43) Pub. Date: Jan. 28, 2010

(54) Cylindrical housing and method of producing same

(76) Inventor: Maximilian Kronberger, Steyr (AT)

Correspondence Address: King & Spalding LLP, 401 Congress Avenue, Suite 3200, Austin, TX, 78701, US

(21) Appl. No.: 12/443,714

(22) PCT Filed: Sep. 28, 2007
(86) PCT No.: PCT/EP07/60345

§ 371 Date: Oct. 16, 2009

(30) Foreign Application Priority Data
Oct. 2, 2006 (DE) 10-2006-046-704.3

(51) Int. Cl. H05K 13/00

(52) U.S. Cl. 29/592.1

(57) ABSTRACT

A cylindrical housing has a coaxial opening having a circular cross-section and at least one line having an oval cross-section, extending parallel to a longitudinal axis. To produce the cylindrical housing, the coaxial opening is produced with a large diameter having at least one bore with a small diameter extending parallel to the opening in a cylindrical blank, and subsequently a mandrel is inserted into the coaxial opening, wherein forces are then applied onto a circumferential surface of the drilled cylindrical blank for the production of the cylindrical housing. Another possibility for production is to roll a metal strip such that a concavity is formed, to create a bore therein and to apply forces in order to level out the concavity. An oval cross-section is imparted on each bore extending in concavities. The metal strip is wound about a mandrel to create the coaxial opening of the circular cross-section.

A method of producing a cylindrical housing is realized which is suitable in particular for receiving a piezoelectric actuator.

Injection systems, in particular leak-oil-free or returnless common-rail injection systems, have a control element which is formed for example by means of a piezoelectric actuator which can optionally be disposed in the fuel high-pressure chamber. In such an arrangement a piezoelectric actuator is provided for the purpose of opening and closing a nozzle by means of a nozzle needle. The piezoelectric actuator has piezoelectric elements arranged in a stack shape, each of which, when an electrical voltage is applied, extends in a vertical direction relative to an electrical field generated by means of the electrical voltage. Piezoelectric elements which consist of piezoceramic materials, made of lead zirconate titanate for example, are characterized by a relatively high operating speed and relatively great efficiency.

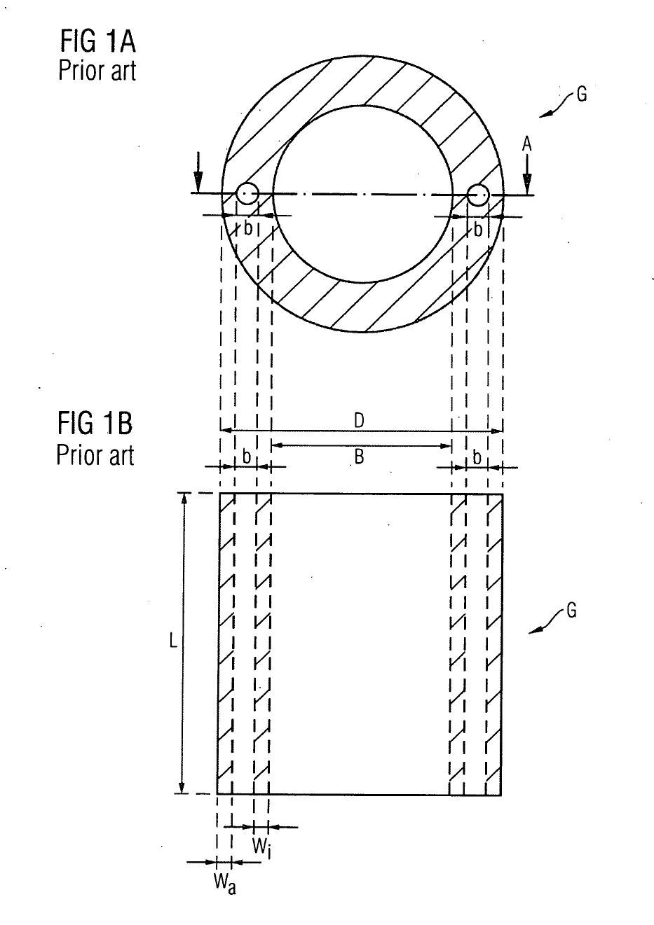

FIG. 1A shows a cross-section through a cylindrical housing G.

FIG. 1B shows a longitudinal section through a cylindrical housing G with a different bore pattern.

The cylindrical housing G has an outer diameter D. Provided in the cylindrical housing G are a large central coaxial bore having a diameter B for receiving the piezoelectric stack S, together with two bores running parallel thereto and having a small diameter b, said bores forming the fuel lines.

The circular cylindrical housing shown in FIGS. 1A, 1B is produced from a cylindrical unprocessed part or blank that has a diameter D and a length L. In this case the length L of the cylindrical blank corresponds to the length L of the cylindrical housing G that is to be produced. During the production process three bores are therefore produced in a cylindrical blank, namely a coaxial bore having a large diameter B and two bores running parallel thereto and having a small diameter b.

This production method has several significant disadvantages, however. The longer the cylindrical housing G is, i.e. the greater the length L, the more difficult it becomes to produce bores that run parallel to the coaxial bore having the large diameter B. In practice it is difficult to produce a bore having a diameter of b <1 mm from a specific length L of approximately 100 mm.

The fuel pressure P that is to be applied by the piezoelectric actuator is very high, with the result that a high pressure prevails in the fuel lines, necessitating a certain minimum wall thickness w. Both the inner wall wᵢ and the outer wall wₐ must not be less than a certain minimum thickness.

In order for the piezoelectric stack to be able to generate the necessary stroke for actuating the nozzle needle, a piezoelectric stack having as large a cross-sectional area as possible is required and consequently a correspondingly large coaxial bore B. The diameter of the coaxial bore B must be at least as large as the outer diameter of a piezoelectric stack S including a passivation, i.e. a passivation layer applied to the piezoelectric stack S, and the electrical contacting. Furthermore, the outer diameter D of the housing G must not exceed the predefined maximum value of, for example, 17 to 19 mm. As a result the maximum diameter of the small bores b is limited due to the restrictions in respect of the outer diameter D and the diameter B of the coaxial bore.

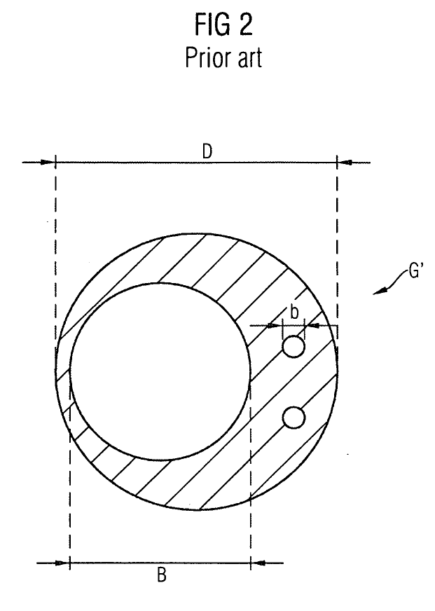

A cylindrical housing G′ has therefore been proposed, as illustrated in FIG. 2. With said cylindrical housing G′, the bore having the large diameter B for receiving the piezoelectric actuator is arranged eccentrically relative to a longitudinal axis of the cylindrical housing. As a result, although it is possible to increase the diameter b of the fuel bores in order thereby to reduce the undesirable pressure drop between the rail port and the nozzle, the eccentric arrangement of the large bore has several serious disadvantages. In the housing G′ illustrated in FIG. 2, the piezoelectric actuator or, as the case may be, the piezoelectric stack S is arranged eccentrically relative to the nozzle D. This is disadvantageous in particular in the case of devices without servo valve having a direct force-fit connection between the piezoelectric actuator and the nozzle needle and a stroke multiplier, since the line of action of the piezoelectric actuator and that of the nozzle needle no longer coincide, with the result that an asymmetric stroke multiplier is required. Due to the eccentric arrangement, lateral forces are also generated, resulting in increased wear as well as energy loss in the stroke multiplier.

It is therefore the object of the present invention to provide a cylindrical housing and a method of producing same wherein the line of action of a suitable actuator runs coaxially and at the same time fuel bores having a maximum cross-section can be produced in a simple manner.

This object is achieved by means of a method having the features recited in claim 1.

A method of producing a cylindrical housing having at least one line running parallel to a longitudinal axis of the housing is described, said method comprising the following steps:
In a cylindrical blank, produce a coaxial opening having a large diameter and at least one bore running parallel thereto and having a small diameter,
introduce a mandrel into the coaxial opening, and
apply forces to a circumferential surface of the drilled cylindrical blank in order to produce the cylindrical housing.

In a preferred embodiment of the method the cylindrical blank consists of a ductile or highly ductile material.

Said ductile or highly ductile material is preferably invar.

In an alternative embodiment of the method the ductile or highly ductile material is steel.

With the method, the outer diameter of the cylindrical housing is embodied in such a way that it is smaller than the outer diameter of the cylindrical blank.

With the method, the length of the cylindrical housing is embodied in such a way that it is greater than the length of the cylindrical blank.

In a preferred embodiment of the method the forces applied to the circumferential surface of the drilled cylindrical blank are generated by cold-forging.

With the method, the cross-section of the at least one parallel-running bore becomes smaller than corresponds to the diameter b of the blank.

In one embodiment of the method a cross-section of a bore running parallel to the coaxial opening and having a small diameter is deformed into an oval shape by the application of the forces onto the circumferential surface of the cylindrical blank.

In this case the longitudinal axis of the cross-section of an ovally shaped bore runs perpendicular to a radius of the produced cylindrical housing.

In a preferred embodiment of the method the bores running parallel to the coaxial opening in an ovally shaped cross-section form fuel lines.

Also achieved is a cylindrical housing having a coaxial opening with a circular cross-section and having at least one line with an oval-shaped cross-section running parallel to a longitudinal axis of the cylindrical housing.

In a preferred embodiment of the cylindrical housing the cylindrical housing has two lines with an oval-shaped cross-section running parallel to the longitudinal axis of the cylindrical housing.

In a preferred embodiment of the housing the coaxial opening is provided for receiving a piezoelectric actuator.

In a preferred embodiment of the housing a longitudinal axis of an oval-shaped cross-section of a line runs perpendicular to a radius of the cylindrical housing.

Furthermore, a method of producing a cylindrical housing is achieved which has a coaxial opening with a circular cross-section and at least one line with an oval-shaped cross-section running parallel to a longitudinal axis of the cylindrical housing, wherein the method comprises the following steps:
Roll a metal strip in such a way that at least one convexity is produced;
produce at least one bore in each resulting convexity in the metal strip;
apply forces for the purpose of leveling the convexities in the metal strip,
   wherein the bores running in the convexities in each case assume an oval-shaped cross-section; and
wind the metal strip around a cylindrical mandrel and join the two ends of the wound metal strip in order to produce a coaxial opening having a circular cross-section.

Also achieved is a method of producing a cylindrical housing which has a coaxial opening with a circular cross-section and at least one line with an oval-shaped cross-section running parallel to a longitudinal axis of the cylindrical housing, wherein the method comprises the following steps:
In the metal strip, produce at least one bore running transversely to a longitudinal axis of the metal strip, said bore running in a plane of the metal strip.
roll out the metal strip, wherein each of the bores running in the metal strip assumes an oval-shaped cross-section; and
wind the metal strip around a cylindrical mandrel and join the two ends of the wound metal strip in order to produce a coaxial opening having a circular cross-section.
cold- or hot-forge so as to produce a circular-cylindrical outer contour.

Preferred embodiments of the cylindrical housing as well as of the method for its production are described in the following with reference to the attached figures for explaining features, in which:

FIGS. 1A, 1B: show cross-sectional views through a cylindrical housing;

FIG. 2: shows a cross-section through a further cylindrical housing;

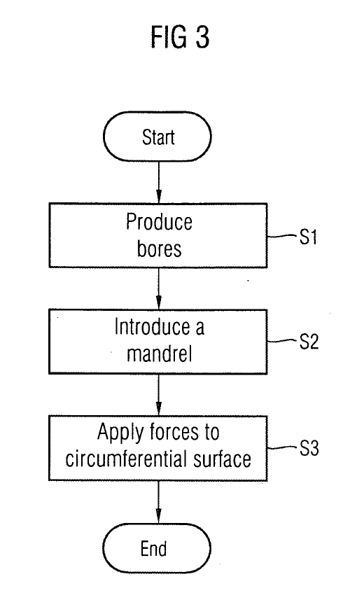

FIG. 3: shows a flowchart for illustrating an embodiment of the production method;

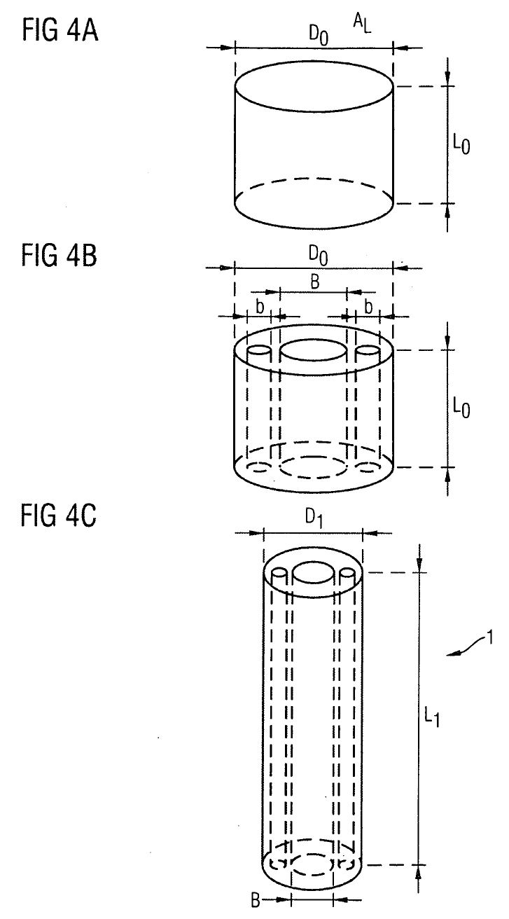

FIGS. 4A, 4B, 4C: show process steps of an embodiment of the production method;

FIG. 5: shows a cross-sectional view to illustrate an insertion of a mandrel into a coaxial bore in accordance with the method;

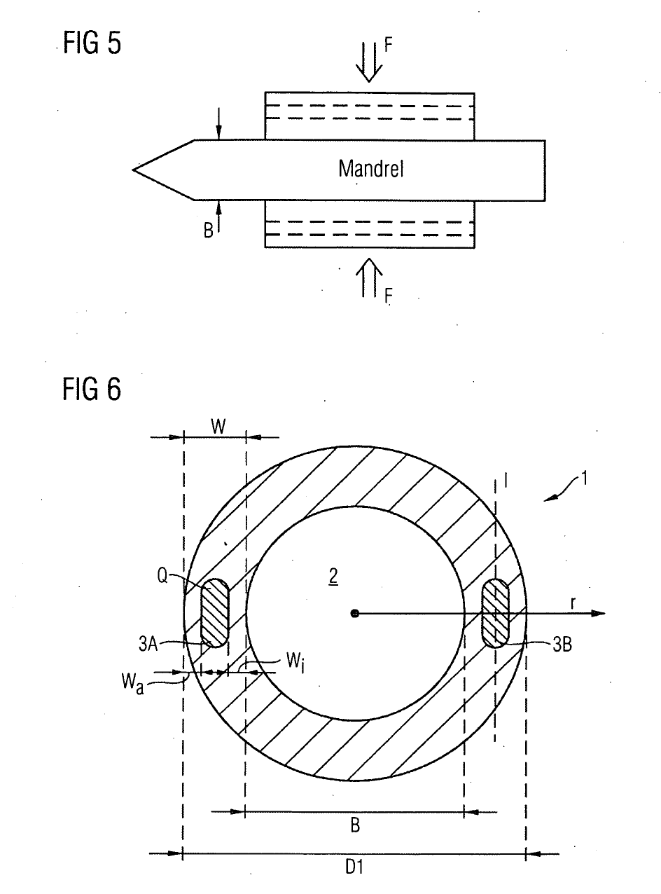

FIG. 6: shows a cross-sectional view through a cylindrical housing.

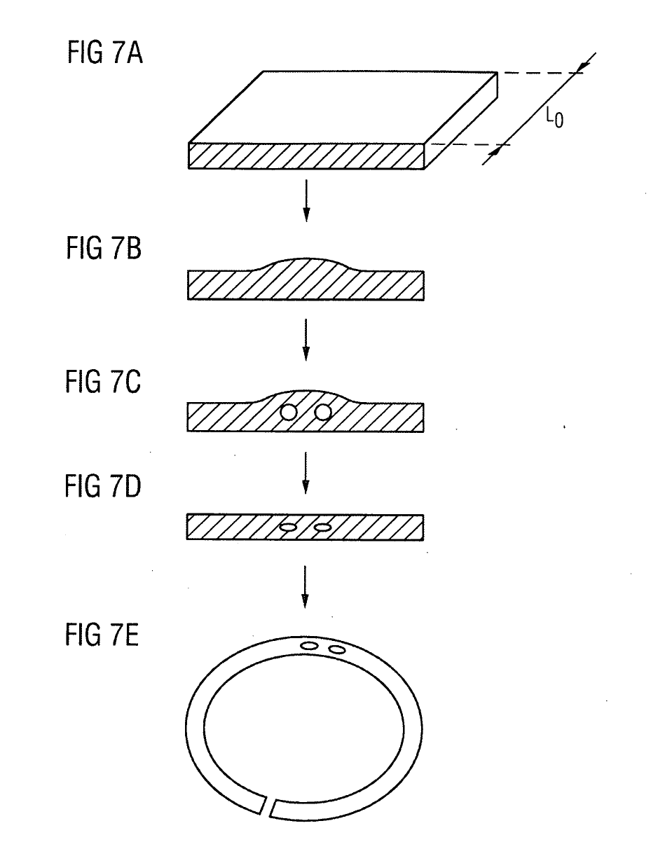

FIGS. 7A-7E: show process steps of an alternative embodiment for producing a cylindrical housing;

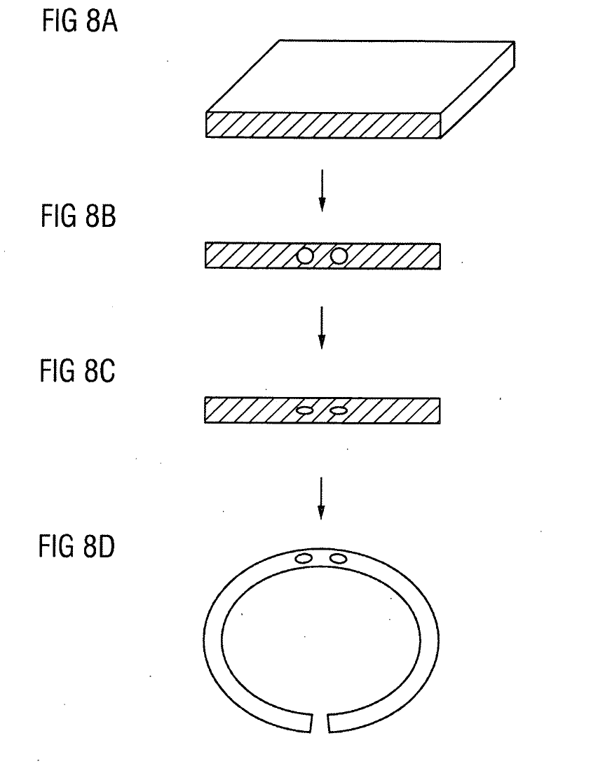

FIGS. 8A-8D: show process steps of a further alternative embodiment for producing the cylindrical housing.

As can be seen from FIG. 3, in one embodiment the method of producing a cylindrical housing essentially consists of three production steps.

In a step S1, bores are first produced in a cylindrical blank, as shown in FIG. 4A. The cylindrical blank has an outer dimension D₀ and a length L₀. The cylindrical blank preferably consists of a ductile material, invar or steel for example. A coaxial bore or opening having a large diameter B is drilled along a longitudinal axis A_{L} of the cylindrical blank, as shown in FIG. 4B. Parallel thereto, two bores having a small diameter b are drilled into the blank. The diameter D₀ of the blank is relatively large and the length of the blank L₀ is relatively small. Owing to the small length L₀ of the blank the bores can be produced in a relatively short time. The smaller bores running parallel to the large bore form the subsequent fuel lines.

After the bores have been produced, in a step S2 of the production method a mandrel is inserted into the coaxial bore having the large diameter B, as shown in FIG. 5. The outer diameter of the mandrel corresponds to the diameter B of the coaxial bore. Large mechanical forces F are then applied to the circumferential surface of the drilled cylindrical blank. The mandrel shown in FIG. 5 protects the large coaxial inner bore against deformation. Because the blank consists of ductile material it is deformed by the application of the large mechanical forces F to the circumferential surface. As a result of the forging process the drilled blank shown in FIG. 4B assumes the shape of the cylindrical housing shown in FIG. 4C. The cylindrical housing 1 shown in FIG. 4C has an outer diameter D₁ and a length L₁. The diameter D₁ of the cylindrical housing 1 is smaller than the initial dimension D₀ of the blank shown in FIG. 4A. The length L₁ of the cylindrical housing is greater than the length L₀ of the cylindrical blank. The cross-section of the coaxial inner bore having a large diameter B remains unchanged by the cold-forging process. The cross-section of the originally circular bores having a small diameter b is altered by the cold-forging process in such a way that the cross-section becomes oval in shape.

FIG. 6 shows a cross-section through the produced housing 1. The cylindrical housing 1 has a coaxial bore or opening 2 with a circular cross-section whose diameter B corresponds to the diameter of the original coaxial bore. Furthermore, the cylindrical housing has two lines 3a, 3b running parallel to the longitudinal axis of the cylindrical housing 1 which have a cross-section that is oval in shape. A longitudinal axis 1 of the oval-shaped cross-section of the bores 3a, 3b in this case runs perpendicular to a radius of the cylindrical housing 1. The cross-sectional area Q of the lines 3a, 3b is relatively large, with the result that an undesirable pressure drop due to the lines 3a, 3b will be minimal. The wall thickness W of the cylindrical housing 1 results from the difference formed from the outer diameter D₁ and the bore diameter B:

W=D₁−B

Owing to the oval shape of the produced lines 3a, 3b it is possible to provide fuel lines 3a, 3b having a relatively large cross-section Q in the walls of the cylindrical housing 1 without the wall thickness wₐ between a fuel line 3a, 3b and an outer surface of the housing 1 or the wall thickness wᵢ between the fuel line 3a, 3b and the inner bore 2 falling below a predefined minimum distance.

The cylindrical housing 1, as it is depicted in FIG. 5C and in FIG. 6, permits the piezoelectric actuator to be inserted into the bore 2 in a line of action with the nozzle needle such that a symmetrical stroke multiplier having a low resulting lateral force can also be provided. This leads to reduced wear and to lower energy requirements.

In addition, the cylindrical housing 1 offers a sufficient cross-section Q of the fuel conduits 3a, 3b with, at the same time, a short extension of the fuel conduits in the radial direction of the housing 1. By this means it is furthermore possible to minimize the number of bores necessary for producing fuel lines in the housing 1. Since the bores are produced on the relatively short blank, the time taken for the drilling operation is short, which means that production costs can be saved. In addition it is considerably easier to align the drill in the case of a relatively short blank and it can be ensured that the coaxial bore 2 for receiving the piezoelectric stack runs exactly parallel to the fuel lines 3a, 3b.

The shape of the cylindrical housing 1 is formed by chipless shaping in step S3, wherein mechanical forces are applied to the circumferential surface of the drilled cylindrical blank.

In the preferred embodiment of the housing 1 shown in FIG. 6 the two bores 3a, 3b are arranged symmetrically in parallel, i.e. they are located opposite each other. In alternative embodiments of the cylindrical housing 1 the bores 3a, 3b can lie at a predefined angle relative to each other.

In the exemplary embodiment shown in FIG. 6 the cylindrical housing 1 has two fuel lines 3a, 3b.

In alternative embodiments more than two lines 3a, 3b are provided in the housing 1, the lines preferably each having an oval-shaped cross-section.

The lines 3a, 3b produced in the fuel housing 1 can be provided for transporting any liquid or any gas.

FIGS. 7A-7E show process steps for illustrating an alternative embodiment for producing the cylindrical housing.

In the embodiment shown in FIG. 7 a metal strip having a width L₀ and a thickness greater than (D-B)/2 is first subjected to a rolling process, resulting in convex shapes being produced. Shown in FIG. 7B, for example, is an upward bulging convexity in the middle of the original metal strip. Next, at least one bore running transversely to the longitudinal axis of the metal strip is produced in the resulting convexity in the metal strip in the plane of the metal strip. In the exemplary embodiment shown in FIG. 7C two bores, for example, are produced in the convexity.

In a further step mechanical forces are applied for the purpose of leveling the upward bulging convexity in the metal strip. This causes the bores running in the upward bulging convexity to assume a cross-section that is oval in shape, as shown in FIG. 7D.

In a further production step the metal strip is then preferably wound around a cylindrical mandrel. The two opposing ends of the wound metal strip are then joined together, by welding for example. This results in a coaxial opening having a circular cross-section.

FIG. 8 shows a further possibility for producing the cylindrical housing.

In this embodiment, as illustrated in FIG. 8B, at least one bore running transversely relative to a longitudinal axis of the metal strip is produced in the plane of the metal strip. The drilled metal strip is then rolled out, as shown in FIG. 8C, wherein the bores running transversely in the metal strip in the process assume an oval-shaped cross-section.

In a further production step the metal strip is then wound around a cylindrical mandrel, for example, and the two opposing ends of the wound metal strip are subsequently joined to each other, for example by welding, thereby producing a coaxial opening having a circular cross-section.

The term “cylindrical” is not limited here just to circular cylindrical embodiments; rather, the term can also be understood to apply to oval or polygonal cross-sectional shapes.

1. A method of producing a cylindrical housing having at least one line running parallel to a longitudinal axis of the housing, said method comprising the following steps:
(a) In a cylindrical blank, producing a coaxial opening having a large diameter and having at least one bore running parallel thereto and having a small diameter;
(b) introducing a mandrel into the coaxial opening
(c) applying forces to a circumferential surface of the drilled cylindrical blank in order to produce the cylindrical housing.

2. The method according to claim 1, wherein the cylindrical blank consists of ductile material.

3. The method according to claim 2, wherein the ductile material is invar.

4. The method according to claim 2, wherein the ductile material is steel.

5. The method according to claim 1, wherein the outer diameter of the cylindrical housing is smaller than the outer dimension of the cylindrical blank.

6. The method according to claim 1, wherein a length of the cylindrical housing is greater than a length of the cylindrical blank.

7. The method according to claim 1, wherein the forces are applied to the circumferential surface of the drilled cylindrical blank by cold-forging.

8. The method according to claim 1, wherein a cross-section of a bore running parallel to the coaxial opening and having a small diameter is deformed into an oval shape by the application of forces to a circumferential surface of the cylindrical blank.

9. The method according to claim 8, wherein a longitudinal axis of the cross-section of an ovally deformed bore runs perpendicular to a radius of the produced cylindrical housing.

10. The method according to claim 9, wherein the bores running parallel to the coaxial opening and having an ovally deformed cross-section form fuel lines.

11. A cylindrical housing comprising:
(a) a coaxial opening with circular cross-section; and having
(b) at least one line with oval-shaped cross-section running parallel to a longitudinal axis of the cylindrical housing.

12. The cylindrical housing according to claim 11, wherein the cylindrical housing has two lines with an oval-shaped cross-section running parallel to the longitudinal axis of the cylindrical housing.

13. The cylindrical housing according to claim 11, wherein the coaxial bore is provided for receiving a piezoelectric actuator.

14. The cylindrical housing according to claim 11, wherein a longitudinal axis of the oval-shaped cross-section of a line runs perpendicular to a radius of the cylindrical housing.

15. The cylindrical housing according to claim 11, wherein with the method the cross-section of the at least one parallel-running bore becomes smaller than corresponds to the diameter of the blank.

16. A method of producing a cylindrical housing said method comprising the following steps:
(a) Rolling a metal strip in such a way that at least one convexity is produced;
(b) producing at least one bore in each resulting convexity in the metal strip;
(c) applying forces for the purpose of leveling the convexities in the metal strip, wherein the bores running in the convexities in each case assume an oval-shaped cross-section; and
(d) winding the metal strip around a cylindrical mandrel and joining the two ends of the wound metal strip in order to produce a coaxial opening having a circular cross-section.

17. A method of producing a cylindrical housing said method comprising the following steps:
(a) In a metal strip, producing at least one bore running transversely to a longitudinal axis of the metal strip, said bore running in a plane of the metal strip;
(b) rolling out the metal strip, wherein each of the bores running in the metal strip assumes an oval-shaped cross-section; and
(c) winding the metal strip around a cylindrical mandrel and join the two ends of the wound metal strip in order to produce a coaxial opening having a circular cross-section.

18. The method according to claim 16, wherein a circular cylindrical outer contour is produced by cold- or hot-forging.

19. The method according to claim 16, wherein with the method the cross-section of the at least one parallel-running bore becomes smaller than the diameter of the blank.

20. The method according to claim 17, wherein a circular cylindrical outer contour is produced by cold- or hot-forging.

21. The method according to claim 17, wherein with the method the cross-section of the at least one parallel-running bore becomes smaller than the diameter of the blank.
